(19) United States
(12) Patent Application Publication
(10) Pub. No.: US 2026/0239634 A1
(43) Pub. Date: Aug. 13, 2026

(54) CAPACITIVE SYNAPTIC DEVICE

(71) Applicant: SEMRON GmbH, Dresden (DE)

(72) Inventor: Kai-Uwe Demasius, Dresden (DE)

(21) Appl. No.: 19/049,961

(22) Filed: Feb. 10, 2025

(51) Int. Cl. H10D 1/64; G06N 3/063; H10D 62/13; H10D 62/60; H10D 64/23

(52) U.S. Cl. CPC H10D 1/64; G06N 3/063; H10D 62/13; H10D 62/60; H10D 64/23

(57) ABSTRACT

This disclosure describes a capacitive synaptic device and the operation of the device. The device includes a semiconductor layer with two distinct regions, each having a specific doping type. A gate electrode is positioned on the semiconductor layer, separated by a dielectric layer. The configuration ensures that neither the gate electrode nor the dielectric layer overlaps the two doped regions.

### BACKGROUND

A disadvantage of resistive devices is their power loss. In contrast, capacitive devices offer significant advantages as they ideally exhibit only reactive power and have no static power consumption. In synaptic devices, achieving the highest possible ratio of minimum to maximum capacitance (dynamic range) is desirable to store as many capacitance values as possible. This goal, however, presents challenges: devices with variable plate distances require a large contrast between the minimum and maximum plate distances, d. A very large d, corresponding to minimum capacitance, would limit lateral scaling to smaller technology nodes. At such large distances, coupling between neighboring cells becomes dominant and undesirable. Conversely, a very small d, corresponding to maximum capacitance, would result in significant tunneling currents between the capacitor plates. For instance, achieving a dynamic range greater than 1:100 with a maximum thickness d of 30 nm would require a minimum thickness of 0.3 nm. At such thicknesses, direct tunneling occurs, negating the low-power consumption advantage of capacitive components. Additionally, varying the plate size introduces lateral scaling issues, while altering the relative dielectric constant limits material choices and allows only a small dynamic range. Therefore, there is a clear need to improve the design and operation of synaptic devices.

### BRIEF DESCRIPTION OF THE DRAWINGS

Various techniques will be described with reference to the drawings, in which:

FIG. 1 illustrates a capacitive synaptic device in accordance with at least one embodiment;

FIG. 2 illustrates another capacitive synaptic device according to at least one embodiment;

FIG. 3 illustrates another capacitive synaptic device according to at least one embodiment;

FIG. 4 illustrates another capacitive synaptic device according to at least one embodiment;

FIG. 5 illustrates another capacitive synaptic device according to at least one embodiment; and

FIG. 6 illustrates a method of operating a capacitive synaptic device according to at least one embodiment.

### DETAILED DESCRIPTION

A capacitive synaptic device and its operation are described. The capacitive synaptic device is capable of having multiple nonvolatile memory states, enabling a high capacitive dynamic range without altering the plate distance, surface area, or relative dielectric constant, while maintaining lateral scalability. Additionally, the capacitive synaptic device may include an extra modulation terminal. In some embodiments, the capacitive synaptic device includes a semiconductor layer designed with variable capacitive coupling properties and thus, in some examples, adjustable field-blocking properties. The semiconductor layer may include one or more connections facilitating charge inflow or outflow. In certain implementations, the semiconductor layer includes a first region and a second region. Both regions may have the same type of doping, or they may differ. For example, the first region might have a first doping type, and the second region might have a second doping type. The first and second doping types could both consist of holes or electrons. Alternatively, the first doping type may consist of holes, and the second doping type may consist of electrons. In some embodiments, the readout of the capacitive synaptic device is performed through one or more of the first or second regions.

One or more of the described capacitive synaptic devices provides significant improvements over other devices by reducing parasitic capacitance. By minimizing these unwanted capacitances, the described capacitive synaptic devices achieve higher overall precision and reliability. This enhanced precision is especially important for post-training quantization processes, a key step when implementing neural networks directly in hardware.

In practical terms, lower parasitic capacitance reduces noise, signal distortion, and power loss, improving the accuracy of data storage and retrieval within the memory cells. This is important for neural network hardware, where even small deviations can accumulate and degrade system performance. With the one or more of the described capacitive synaptic devices, post-training quantization techniques can be executed more effectively, allowing neural networks to run at lower bit depths without compromising accuracy. In some implementations, a gate electrode is disposed on the semiconductor layer, and a dielectric layer is positioned between the gate electrode and the semiconductor layer. In at least one embodiment, the gate electrode or the dielectric layer is configured so as not to overlap the first region or the second region. In another embodiment, both the gate electrode and the dielectric layer are configured not to overlap either the first region or the second region. This non-overlapping configuration ensures that the device has a high dynamic range.

In at least one embodiment, electric field lines from the gate electrode either terminate on or within the semiconductor layer when inversion or accumulation of the semiconductor layer is strong. Alternatively, when depletion of the semiconductor layer is strong, electric field lines from the gate electrode predominantly reach one or more of the first or second regions. As a result, the operation of the semiconductor layer influences the coupling of the electric field from the gate electrode to one or more of the first or second regions. A high dynamic range is ensured primarily through ensured by large non-overlapping distances of one or more of the first or second regions and the thickness of the semiconductor layer. This approach is fundamentally different from conventional devices, where the dynamic range is achieved by varying the distance between capacitor plates, a method associated with significant disadvantages. In contrast, the described devices provide a sufficiently high dynamic range with thin layers, allowing for better lateral scalability.

In at least one embodiment, the dielectric layer and/or the semiconductor layer act as active storage media. The operation point of the semiconductor layer can be nonvolatilely stored (i.e., persistently stored), either directly within the semiconductor layer or through an interaction between the dielectric layer and the semiconductor layer, with the storage function originating from the dielectric layer. Additionally, the dielectric layer can be designed as an active storage medium capable of storing various charge states. These stored charge states can shift the voltage threshold at which the semiconductor layer transitions to a strong field-blocking condition. For instance, the capacitance-voltage curves in the semiconductor layer may shift due to the charge states in the dielectric layer. In some embodiments, these charge states are nonvolatilely stored in the dielectric layer.

In at least one embodiment, the dielectric layer is an active storage medium made from a ferroelectric material. This material features electrical polarization states that can be arbitrarily adjusted between positive and negative polarization through domain formation. For example, the dielectric layer can serve as an active storage medium that stores various charge states. The active storage medium may include one or more charge-trapping sites. These charge-trapping sites can be formed by a nitride layer and/or a polycrystalline layer within the dielectric layer. Additionally, charges can be stored in a nonvolatile manner within the dielectric layer in at least one embodiment.

In at least one embodiment, the first dielectric layer and/or the semiconductor layer are designed as an active storage medium. In an example, the semiconductor layer may function as a storage medium capable of holding various resistance values. This capability is enabled by equipping the semiconductor layer with a variable resistance that can nonvolatilely store its resistance value. In at least one embodiment, the semiconductor layer can achieve its variable resistance through an adjustable capacitance of the semiconductor layer.

In at least one embodiment, the semiconductor layer includes a nonvolatile storage function. For example, when the semiconductor layer has high resistance, few field-blocking charges flow in, allowing the electric field from the gate electrode to pass through. Conversely, if the semiconductor layer has low resistance, it exhibits a strong blocking effect on the electric field. In at least one embodiment, the adjustable capacitance of the semiconductor layer governs its ability to impede or transmit the field. In at least one embodiment, the electrical field from the gate electrode can be read out through one or more regions of the semiconductor layer, such as doped regions. The semiconductor layer can be formed from a metal-insulator-transition material, a memristive material, and/or a phase-change memory material.

In at least one embodiment, the semiconductor layer may include a semiconductor material that exhibits a nonlinearity in the capacitance-voltage relationship of the capacitive coupling between the gate electrode and one or more regions of the semiconductor layer.

Various semiconductor materials are well-suited for use in the semiconductor layer to achieve variable field-blocking behavior. For instance, the semiconductor layer can be driven into inversion or accumulation by applying a suitable voltage to the gate electrode, creating a strong blocking effect. In contrast, if the semiconductor material is substantially depleted, it provides weaker blocking. This creates a capacitive coupling window for a specific voltage range of the gate electrode. Since inversion and accumulation layers are very thin—particularly under strong inversion or accumulation—the semiconductor layer itself can also be thin while still offering a wide dynamic range.

In at least some embodiments, the semiconductor layer may feature laterally highly doped p- and n-regions, with the area in between being only lightly doped or intrinsic, forming a psn- or pin-region. In an example, readout is performed through the semiconductor layer and specifically through one or more of the laterally highly doped p- and n-regions. The laterally doped p- and n-regions enable the injection of holes and electrons, which facilitates good inversion and accumulation in one or more portions of the semiconductor layer. This results in symmetric blocking behavior for both positive and negative gate voltages. Such symmetric behavior is important in synaptic components to achieve high accuracy. Furthermore, the psn- or pin-region offers additional modulation possibilities through the application of a lateral voltage difference. The “s” in psn indicates weak doping compared to the p- and n-regions.

In at least one embodiment, the semiconductor layer and the dielectric layer can be made from a single contiguous semiconductor material. This approach can simplify the manufacturing process of the capacitive synaptic device. In an example, the dielectric layer is formed in the single contiguous semiconductor material by way of depletion.

In at least one embodiment, a shielding layer is disposed on the gate electrode. Furthermore, in an example, the shielding layer disposed on the gate electrode is designed to prevent parasitic capacitance between the gate electrode and one or more of regions of the semiconductor layer. In at least one embodiment, the shielding layer covers the gate electrode. In an example, the shielding layer covers the gate electrode but does not overlap with doped regions of the semiconductor layer. In at least one embodiment, an insulator, such as a thin oxide, is disposed between the shielding layer and the gate electrode layer.

In an example, an insulator is disposed on the semiconductor layer. In at least one embodiment, the insulator is disposed below the semiconductor layer. In an example, an electrode, such as an electrode layer, is disposed on the insulator. The insulator and/or the electrode layer can be configured to prevent and/or reduce parasitic capacitance or signal coupling between the capacitive synaptic device and another capacitive synaptic device proximate to the capacitive synaptic device.

In various examples, a matrix composed of multiple capacitive synaptic components is used. In this matrix, a word line of each component connects to the gate electrode, one or more of the doped regions can be connected to the bit line. In some examples, the bit lines are arranged at a non-zero angle, preferably 90°, to the word lines.

Artificial neural networks require numerous vector-matrix multiplications, where the weights are stored within the matrix. To optimize this process, arranging the synaptic components in a matrix format is advantageous. The gate electrodes connect to the word lines, the one or more of the doped regions to the bit lines, and portions of the semiconductor layer connect to the shielding lines. Shielding lines run parallel to the bit lines, which are positioned perpendicularly to the word lines. Input signals, represented as vector values, are applied to the word lines. These signals are weighted within the capacitive synaptic components based on the configured shielding and then summed along the bit lines. The aggregated results are subsequently read from the bit lines. Writing to the matrix occurs between the bit lines and the word lines.

Writing to and reading from the proposed capacitive synaptic device can involve several steps. The first step is a non-volatile field-blocking adjustment, where a write voltage is applied between the gate electrode and the semiconductor layer. This process establishes different electrical states in the active storage medium by varying the write pulse height, pulse duration, or pulse count. A potential difference between the gate electrode and the semiconductor layer facilitates the storage of specific states. For instance, in the case of charge trapping, charges are injected into the dielectric layer through quantum mechanical tunneling. For ferroelectric materials, changes occur in the polarization state. When dealing with adjustable resistance, influenced by an adjustable capacitance, writing modifies the capacitance by inducing a metal-insulator transition or shifting oxygen vacancies. These methods enable quasi-analog value storage by fine-tuning the parameters of the write pulse.

The method further includes volatile adjustment of electric field effects, where a direct current (DC) or symmetric blocking/conduction voltage is applied to the semiconductor layer to influence the pin- or psn-transition. Temporary adjustments to electric field effects can also be achieved by applying a voltage to the semiconductor layer. For lateral p- and n-regions, blocking or conduction through the pin- or psn-diode can deplete or accumulate mobile charge carriers, thereby modifying the field distribution. Additionally, applying the same DC voltage to terminals of the semiconductor layer can shift the gate voltage range for depletion in semiconductor materials. This adjustment effectively shifts capacitance-voltage curves and alters the transmission or field dynamics.

In at least one embodiment, during the reading of capacitive coupling between the gate electrode and one or more of the doped regions of the semiconductor layer, the semiconductor layer can be grounded. Alternatively, in at least one embodiment, voltage conditions at the semiconductor layer remain consistent with those described in the volatile adjustment process.

In an example, during the variable input signal application, a variable input signal is applied to the gate electrode. Depending on the level of field-blocking, a change in current or charge is measured at one or more of the doped regions of the semiconductor layer.

During simple reading without non-volatile modulation, the semiconductor layer is grounded, and an alternating voltage signal is applied to the gate electrode. The ability of the semiconductor layer to regulate electric field interaction determines the coupling to the readout electrode, which can be one or more of the doped regions of the semiconductor layer. For reading with non-volatile modulation, the voltage of the semiconductor layer is maintained to enable modulation. As in simple reading, an alternating voltage signal is applied to the gate electrode.

When applying this method to the proposed matrix arrangement, variable voltage signals are applied simultaneously to all word lines during reading. At the intersection points, weighted multiplication occurs, while the resulting currents or charge changes are summed along the bit lines. The inputs—representing the vector values in vector-matrix multiplication—are the alternating signals applied to the word lines. The outputs, corresponding to the results of the multiplication, are the summed currents or accumulated charges from the bit lines.

In at least some embodiments, the semiconductor layer contains highly doped p- and n-regions separated by a lightly doped or intrinsic area, forming a psn- or pin-region. Writing to the active storage medium can be modulated by applying a symmetric blocking or conduction voltage to the psn- or pin-transition. By actively adding or removing charge carriers in the semiconductor layer at these transitions, the writing process to the dielectric layer can be either suppressed or enhanced. This modulation depends on the availability of sufficient charges in the semiconductor layer to create a strong enough field in the dielectric layer for writing. When the layer is depleted of charge carriers, the electric field couples primarily to one or more of the highly doped p- and n-regions, reducing the potential across the dielectric layer. In at least one embodiment, the device mimics a sigmoid or ReLU (Rectified Linear Unit) neuron. Neurons can be turned on or off during the dropout algorithm by applying a symmetric blocking or conduction voltage to the psn- or pin-transition. In at least one embodiment, the device is designed to emulate various neuron-like behaviors, such as those associated with non-linear activation functions, thereby making the device suitable for applications in neuromorphic computing and systems.

During neural network training, overfitting—an undesirable condition—can be mitigated by selectively disabling neurons and gradually re-enabling them. The capacitive synaptic device is inherently well-suited for modeling ReLU and sigmoid neurons because its capacitive coupling transfer function exhibits similar behavior. These neurons can be activated or deactivated by enriching or depleting the semiconductor layer with charge carriers.

In at least one embodiment, writing to the capacitive synaptic device is by using Fowler-Nordheim tunneling or by injecting hot charge carriers, which can be produced in the pin- or psn-transition by applying a suitable voltage. For example, when writing to the dielectric layer that contains charge trapping sites, these sites can be filled with charge carriers either through Fowler-Nordheim tunneling or by injecting hot carriers. Hot carrier generation can also be facilitated by the lateral psn- or pin-transition. In the blocking region, applying sufficiently high blocking voltages can produce an adequate number of hot charge carriers for this purpose.

When writing to the first dielectric layer that contains charge trapping sites, these sites can be filled with charge carriers either through Fowler-Nordheim tunneling or by injecting hot carriers. Hot carrier generation can also be facilitated by the lateral psn- or pin-transition. In the blocking region, applying sufficiently high blocking voltages can produce an adequate number of hot charge carriers for this purpose.

In the preceding and following description, various techniques are described. For purposes of explanation, specific configurations and details are set forth in order to provide a thorough understanding of possible ways of implementing the techniques. However, it will also be apparent that the techniques described below may be practiced in different configurations without the specific details. Furthermore, well-known features may be omitted or simplified to avoid obscuring the techniques being described.

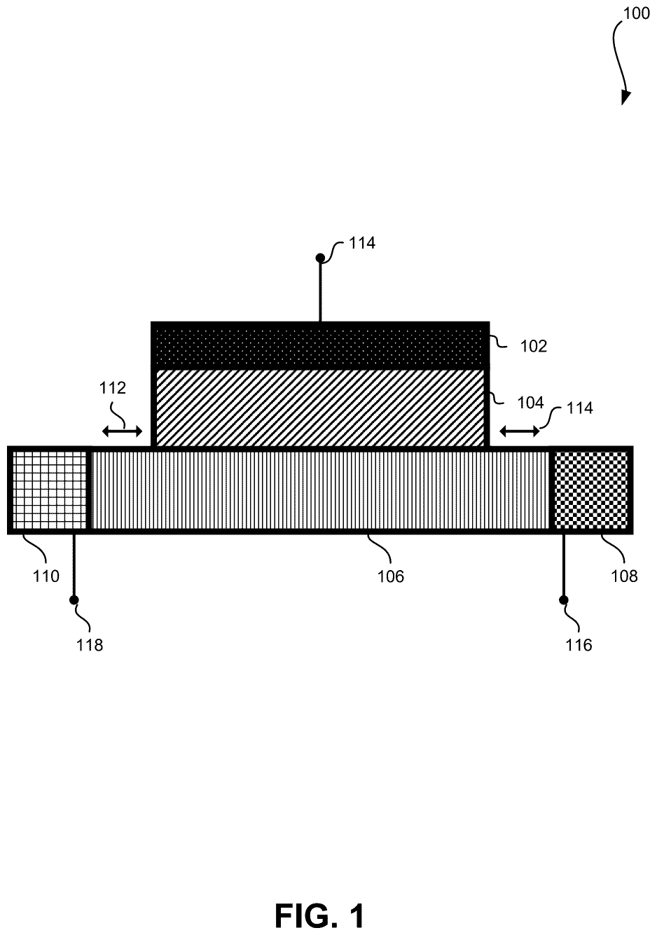

FIG. 1 illustrates a capacitive synaptic device 100 according to at least one embodiment. Although the figure shows a number of layers, this representation is merely an example. The device 100 may include more layers or fewer layers than those depicted.

In at least one embodiment, the device 100 includes an electrode layer 102. The electrode layer 102 is often referred to herein as simply electrode 102 or gate electrode 102. The electrode layer 102 can be formed of one or more materials that provide both good electrical conductivity and compatibility with and/or one or more fabrication processes used to form the device 100. In various examples, the electrode layer 102 can comprise aluminum, copper, gold, silver, titanium silicide, cobalt silicide, nickel silicide, tungsten, titanium nitride, and/or doped polycrystalline silicon.

The electrode layer 102 can be disposed on a dielectric layer 104. In at least one embodiment, the dielectric layer 104 is configured to store a charge that represents a binary bit (1 or 0) or a plurality of binary bits. In an example, the dielectric layer 104 serves as a charge storage medium and/or as a barrier to confine and maintain a charge. In at least one embodiment, the dielectric layer 104 can be made of silicon dioxide, silicon nitride, an oxide-nitride-oxide stack, one or more high-k dielectrics, and/or a combination of oxide, nitride, and other high-k materials.

The dielectric layer 104, in at least one embodiment, is disposed on a semiconductor layer 106. In at least one embodiment, the semiconductor layer 106 is between 10-30 nm thick. The semiconductor layer 106 can include a first region 108 and a second region 110. In some examples, the first region 108 is doped using a first doping type. The second region 110 is doped using a second doping type. The first doping type and the second doping type can be the same. Alternatively, in some embodiments, the first doping type is different from the second doping type. In various examples, the first doping type of the first region 108 comprises electrons. Similarly, the second doping type 110 can comprise electrons. In another example, the first doping type of the first region 108 comprises holes. Similarly, the second doping type 110 can comprise holes.

In at least one embodiment, the electrode layer 102 is configured so as to not overlap the first region 108. The electrode layer 102 can also be configured so as to not overlap the second region 110. In at least one embodiment, the electrode layer 102 is configured to neither overlap the first region 108 nor the second region 110.

The dielectric layer 104 can also be configured so as to not overlap the first region 108. Furthermore, the dielectric layer 104 can also be configured so as to not overlap the second region 110. In at least one embodiment, the dielectric layer 104 is configured to neither overlap the first region 108 nor the second region 110.

In at least one embodiment, a distance 112 from a boundary of the electrode layer 102 and/or the dielectric layer 104 is at least 0.1 times a total length of the electrode layer 102 and/or the dielectric layer 104. In an embodiment, the distance 112 is from a lateral side of the layer 102 and/or layer 104 to a lateral side of the second region 110. Similarly, in at least one embodiment, a distance 114 from a boundary of the electrode layer 102 and/or the dielectric layer 104 is at least 0.1 times a total length of the electrode layer 102 and/or the dielectric layer 104. In an embodiment, the distance 114 is from a lateral side of the layer 102 and/or layer 104 to a lateral side of the first region 108. In at least one embodiment, one or more of the distances 112 or 114 reduces stray coupling, such as caused by electrical field, from the electrode layer 102 and/or the dielectric layer 104 to the semiconductor layer 106. In an example, one or more of the distances 112 or 114 reduces stray coupling from the electrode layer 102 and/or the dielectric layer 104 to one or more of the first region 108 or the second region 110. In at least one embodiment, one or more of the distances 112 or 114 are not greater than a maximum depletion width in the semiconductor layer 102. In at least one embodiment, the one or more of the distances 112 and/or 114 are caused during a manufacturing process of the device 100. For example, the distances 112 and/or 114 can be generated by spacer pattering during the manufacturing process of the device 100. The spacer pattering can used to generate and/or adjust the distances 112 and/or 114 based on a self-aligned spacer process during manufacturing of the device 100. For example, once the electrode layer 102 and/or the dielectric layer 104 are disposed, a spacer deposition is made and then etched to generate and/or adjust the distances 112 and/or 114.

In at least one embodiment, readout, such as readout of a charge stored in the dielectric layer 104, can be performed through the semiconductor layer 106. For example, readout can be performed via the first region 108 and/or the second region 110. In an example, a terminal 116 can be coupled to the first region 108. The terminal 116 can facilitate readout of a charge stored in the dielectric layer 104. In some examples, a terminal 118 can be coupled to the second region 110. The terminal 118 can facilitate readout of a charge stored in the dielectric layer 104.

The device 100 can receive a write voltage at the electrode layer 102. This write voltage can cause charge to be stored in the dielectric layer 104. In at least one embodiment, the write voltage can have a varying pulse duration and/or pulse height. In at least one embodiment, a plurality of write pulses is applied to the electrode layer 102 to cause charge to accumulate in the dielectric layer 104. In an example, the write voltage is applied to the electrode layer 102 via a terminal 120. In at least one embodiment, the dielectric layer 104 can comprise ferroelectric material to store charge. In other examples, or in addition, the dielectric layer 104 can comprise one or more charge trapping sites to store charge. In at least one embodiment, charge can be stored in the dielectric layer 104 by generating a potential difference between the electrode layer 102 and the semiconductor layer 106. In at least one embodiment, this potential difference is caused at the terminals 114 and 116, or at the terminals 114 and 118, or at the terminal 114 and the terminals 116 and 118.

In various implementations, the semiconductor layer 106 moderates the electric field applied to the electrode layer 102. This electric field can cause charge to accumulate in the dielectric layer 104. For example, increasing the storage state or charge accumulation in the dielectric layer 104 can be achieved by applying a write voltage between terminal 114 and one or more of terminals 116 and 118. This write voltage may include one or more write pulses. The charge state of the dielectric layer 104 can be influenced by adjusting the write pulse duration, pulse height, and/or the number of pulses. When the dielectric layer 104 includes a ferroelectric material, the potential difference generated between terminals 114 and 116 and/or 118 leads to a gradual change in the material's polarization state. Alternatively, when the dielectric layer 104 includes one or more charge-trapping sites, charge accumulation is driven by variations in the quantum mechanical tunneling strength of charge carriers originating from the semiconductor layer 106.

In at least one embodiment, a high degree of field isolation, such as during writing to the device 100, arises due to inversion or accumulation in the semiconductor layer 106. This inversion or accumulation can be induced by a voltage applied to the gate electrode layer 102. For example, when the gate electrode layer 102 is driven to a voltage sufficient to invert the surface type of the semiconductor layer 106 (from p-type to n-type or vice versa), a thin but highly conductive layer forms at the surface, providing strong field attenuation. Similarly, if a voltage on the gate electrode layer 102 causes carriers (electrons or holes) to accumulate in the semiconductor layer 106, a conductive region emerges that also strongly reduces external field effects. In both cases (inversion or accumulation), this conductive layer in the semiconductor layer 106 acts like a metallic barrier that effectively blocks or impedes signal flow, resulting in significant field isolation contributed by the semiconductor layer 106.

In some implementations, the semiconductor layer 106 is depleted during readout for the device 100. For example, a voltage at the gate electrode layer 102 can deplete the semiconductor layer 106 of charge carriers rather than causing inversion or accumulation. As a result, no conductive layer forms in the semiconductor layer 106. In this condition, the semiconductor layer 106 does not interfere with the passage of the electric field or charge, allowing coupling through to one or more of the regions 108 or 110. In at least one embodiment, during readout of the device 100, a variable voltage signal is applied to the gate electrode layer 102 (for instance, via terminal 114). Moreover, during readout, the semiconductor layer 106 is grounded or connected to a direct current (DC) potential. This process effectively shifts the capacitance-voltage curve, enabling charge to transfer, via capacitive coupling, through one or more of the regions 108 or 110.

In at least one embodiment, capacitive coupling associated with the device 100 can be influenced by applying a voltage, such as ±7 V, to one or more of the regions 108 or 110, such as by applying the voltage to one or more of the terminals 116 or 118. The applied voltage can deplete the semiconductor layer 106. When the semiconductor layer 106 is depleted, the capacitance-voltage curve broadens, which allows electrical signal or charge flow from the gate electrode layer 102 and/or the dielectric layer 104 through one or more of the regions 108 or 110. Conversely, in at least one embodiment, the applied voltage can flood the semiconductor layer 106 with mobile charge carriers. Under this condition, the capacitance-voltage curve is narrowed and/or lowered, increasing the semiconductor layer 106's ability to block or isolate electrical signals or charge from traveling between the gate electrode layer 102 and/or the dielectric layer 104 and one or more of the regions 108 or 110.

By adjusting the voltage applied to the gate electrode layer 102, there is a range in which the ability of the semiconductor layer 106 to isolate or block field effects transitions from weak to strong. Specifically, by tuning the voltage applied to the gate electrode layer 102 as well as a potential condition(s) associated with the semiconductor layer 106, the readout at one or more of the regions 108 or 110 is controlled by a certain degree of capacitive coupling to the signals and/or charges associated with the layers 102 and/or 104. Thus, the voltage applied to the gate electrode layer 102 as well as a potential condition associated with the semiconductor layer 106 causes the device 100 to provide a voltage-controlled window for electric fields.

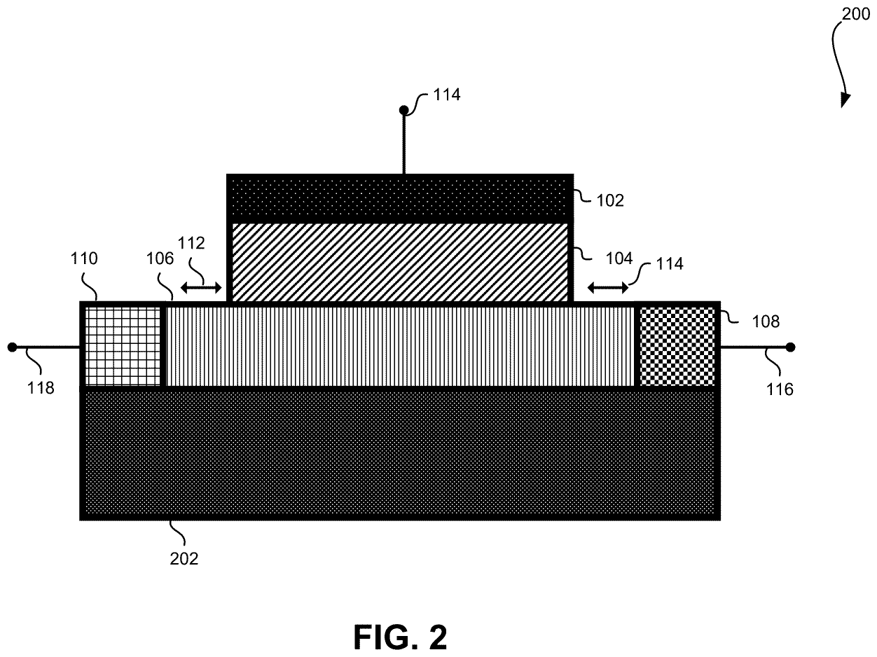

FIG. 2 illustrates another capacitive synaptic device 200 according to at least one embodiment. Although the figure shows a number of layers, this representation is merely an example. The device 200 may include more layers or fewer layers than those depicted. In at least one embodiment, the device 200 is a modified version of the device 100.

The device 200 may include a layer 202. This layer 202 can be placed on the semiconductor layer 106. In at least one embodiment, the layer 202 is below the semiconductor layer 106. In at least one embodiment, the layer 202 is an oxide layer. The layer 202 may serve to insulate one or more of the layers 102, 104, or 106 from a substrate associated with the device 200. In at least one embodiment, the layer 202 is positioned on the semiconductor layer 106 to reduce or prevent signal coupling to an underlying substrate associated with the device 200. The layer 202 can be partially or entirely disposed within a trench in the substrate associated with the device 200.

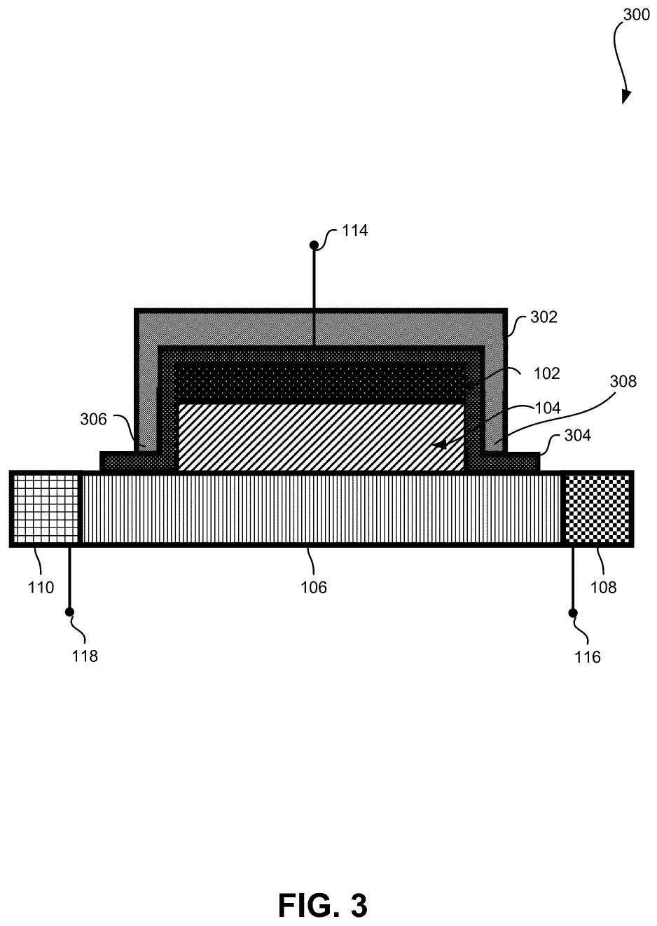

FIG. 3 illustrates another capacitive synaptic device 300 according to at least one embodiment. Although the figure shows a number of layers, this representation is merely an example. The device 300 may include more layers or fewer layers than those depicted. In at least one embodiment, the device 300 is a modified version of the device 100 and/or 200.

In an implementation, a layer 302 is disposed on the gate electrode 102. In some implementations, the layer 302 may also be disposed on the semiconductor layer 106. In an implementation, the layer 302 is a shielding layer. For example, the layer 302 can be made of metal with polysilicon. In at least one embodiment, the layer 302 can comprise a type of metal, such as aluminum, copper, or tungsten. As an alternative, the layer 302 can include a metal nitrides, such as titanium nitride or tantalum nitride. In at least one embodiment, the layer 302 can include doped poly silicon.

The device 100 can also comprise a layer 304. The layer 304 can be disposed on the semiconductor layer 106. In at least one embodiment, the layer 304 can be disposed on the semiconductor layer 106 and the electrode layer 102. In an example, the layer 304 is disposed between the layer 302 and the electrode layer 102. The layer 304 can be an insulating layer. Therefore, the layer 304 can comprise oxide, such as a thin oxide layer. The layer 304 can have a thickness ranging between 5-20 nm.

In at least one embodiment, the layer 302 has a boundary 306 positioned on the layer 304. The layer 302 can also have another boundary 308 positioned on the layer 304. In one example, a portion of the layer 304 extends beyond a lateral edge of the boundary 306. Similarly, a portion of the layer 304 extends beyond a lateral edge of the boundary 308. The portion of the layer 304 that extends beyond the lateral edge of the boundary 306 can be disposed on the semiconductor layer 106. In at least one embodiment, the portion of the layer 304 that extends beyond the lateral edge of the boundary 306 does not overlap with the region 110. Similarly, the portion of the layer 304 that extends beyond the lateral edge of the boundary 308 can be disposed on the semiconductor layer 106. In one example, the portion of the layer 304 that extends beyond the lateral edge of the boundary 308 does not overlap with the region 108. In some examples, the boundary 306 of the layer 302 extends and ends substantially at the boundary or end of the layer 304. Similarly, in some examples, the boundary 308 of the layer 302 extends and ends substantially at the other boundary or end of the layer 304.

In some implementations, the layer 302 is positioned to reduce or eliminate an electrical field, for example such as an electrical field applied to the electrode layer 102, from influencing one or more of the regions 108 or 110. The layer 302 can be coupled to a voltage, such as an alternating current (AC) voltage, or to ground. This coupling of the layer 302 can block an electrical field associated with the layer 102 from reaching one or more of the regions 108 or 110.

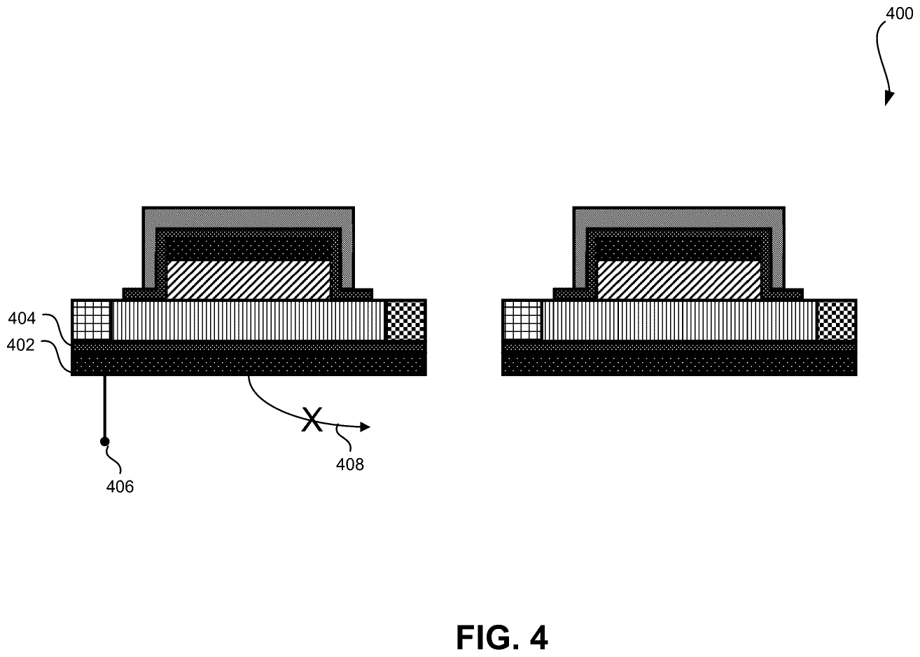

FIG. 4 illustrates another capacitive synaptic device 400 according to at least one embodiment. Although the figure shows a number of layers, this representation is merely an example. The device 400 may include more layers or fewer layers than those depicted. In at least one embodiment, the device 400 is a modified version of the device 100, 200, and/or 300.

The device 400 can include layers 402 and 404. A terminal 406 may be coupled to layer 402. FIG. 4 shows two instances of device 400 (i.e., a first device 400 and a second device 400) to help explain why, in one example, the device 400 may be manufactured with both layers 402 and 404. In at least one embodiment, the layer 402 is similar to or the same as the layer 302 and/or the layer 102. Furthermore, in some examples, the layer 404 is similar to or the same as the layer 304.

The layer 402 is positioned to reduce or eliminate electric fields—such as those applied to the electrode layer 102 or present in any layers of the first device 400—from influencing layers of the second device 400 located near the first device 400. The layer 402 may be coupled to a voltage source (e.g., an AC voltage) or to ground. By coupling the layer 402 in this manner, the electric field 408 associated with the layer 402 is prevented from reaching the adjacent second device 400. In at least one embodiment, the layer 402 is coupled to the voltage source or ground via the terminal 406.

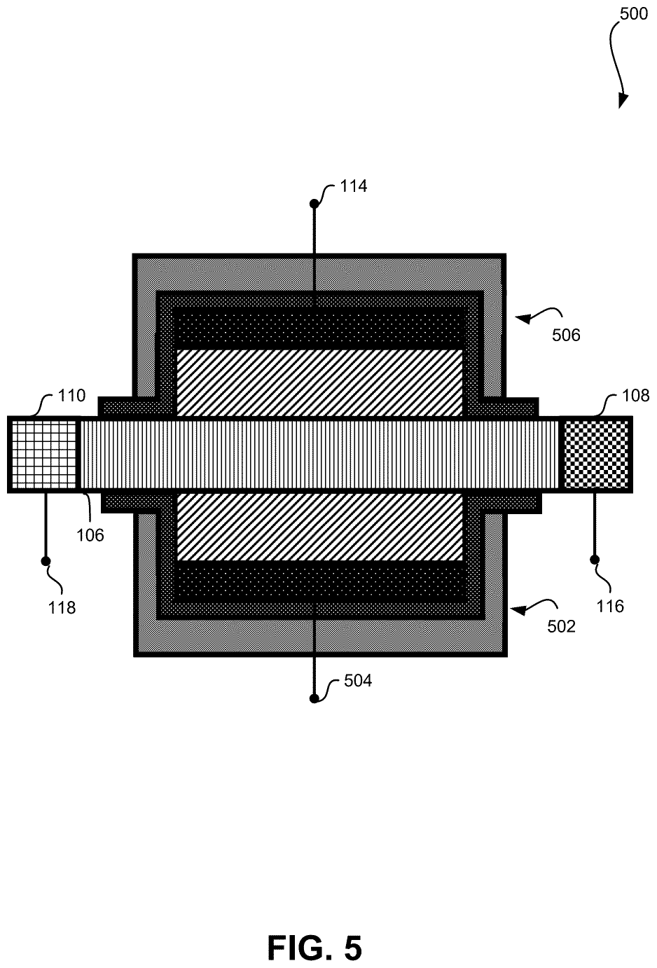

FIG. 5 illustrates another capacitive synaptic device 500 according to at least one embodiment. Although the figure shows multiple layers, this illustration is merely an example. The device 500 may include more layers or fewer layers than those depicted. In at least one embodiment, the device 500 is a modified version of device 100, 200, 300, and/or 400.

In at least one embodiment, the device 500 is the same as device 300 but includes an additional layer stack 502 that may contain one or more of the following: a shielding layer, an insulating layer, an electrode layer, or a dielectric layer. In at least one embodiment, the additional layer stack 502 is disposed on the semiconductor layer 106 and can include a terminal 504. The additional layer stack 502 can be programmed (e.g., written to) separately or differently than the layer stack 506, for instance by applying signals through terminal 504. In some implementations, various layers of the additional layer stack 502 may differ from those of layer stack 506. For example, in at least one embodiment, the dielectric layer in the additional stack 502 has a different thickness (e.g., height) than the dielectric layer in the layer stack 506.

In at least one embodiment, one or more of the described devices 100, 200, 300, 400, and/or 500 can be arranged vertically and/or horizontally in two-dimensional (2D) and/or three-dimensional stacks (3D). For example, in 2D stacking, one or more of the described devices 100, 200, 300, 400, and/or 500 can be placed side by side on a single vertical or horizontal plane (the same substrate). This approach allows for more circuitry to be integrated on a single layer without necessarily increasing the die size substantially in the vertical direction. In 3D stacking, one or more of the described devices 100, 200, 300, 400, and/or 500 are stacked vertically or horizontally on top of one another. These layers can be electrically connected through interconnects. 3D stacking of one or more of the described devices 100, 200, 300, 400, and/or 500 can greatly reduce the footprint on the board, shorten signal paths, and enable higher bandwidth and lower power consumption compared to placing individual chips side by side.

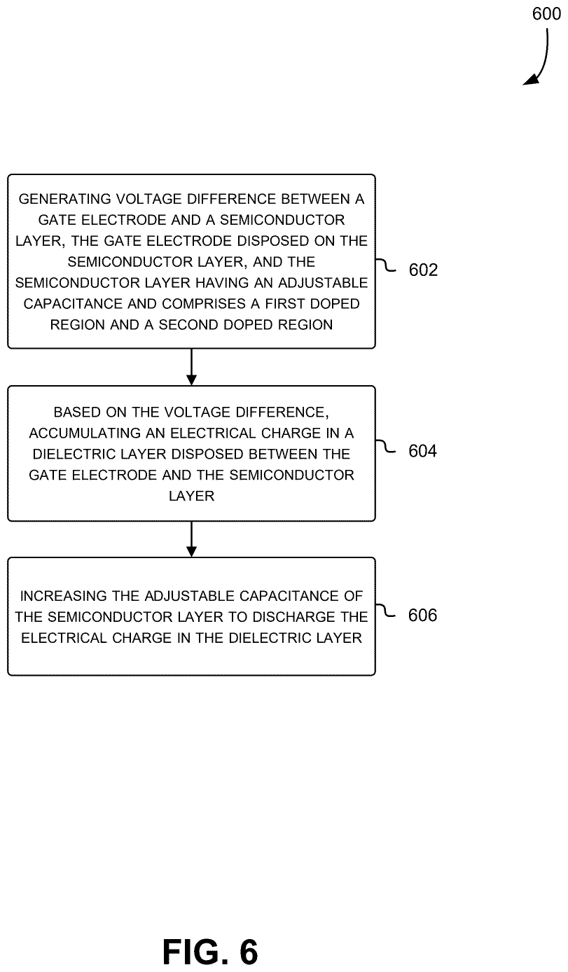

FIG. 6 illustrates a method 600 of operating a capacitive synaptic device according to at least one embodiment. In at least one embodiment, the method 600 applies to one or more of the described devices 100, 200, 300, 400, and/or 500.

At 602, a voltage difference is established between the gate electrode and the semiconductor layer. The gate electrode may be disposed on top of the semiconductor layer, and the semiconductor layer can feature an adjustable capacitance or a high capacitive dynamic range, and it includes a first doped region and a second doped region. The adjustable capacitance of the semiconductor layer can be influenced by the inflow and outflow of charge from the semiconductor layer. In some embodiments, the adjustable capacitance of the semiconductor layer regulates the coupling of the electrical field from the gate electrode layer to one or more doped regions within the semiconductor layer.

In certain embodiments, the capacitive synaptic device includes a dielectric layer capable of storing multiple charge states. These various charge states can influence the shielding attribute of the semiconductor layer. For example, a capacitance-voltage curve can shift in the semiconductor layer due to various charge states associated with other layers of the capacitive synaptic device, such as the dielectric layer and/or the gate electrode layer. This shifting capacitance-voltage curve can influence how the semiconductor layer blocks or transmits electrical charge.

At 604, based on the voltage difference, an electrical charge is accumulated in the dielectric layer disposed between the gate electrode and the semiconductor layer. In at least one embodiment, a write voltage is applied between the gate electrode and the semiconductor layer. This write voltage can cause electrical charge to accumulate in the dielectric layer. Accumulation of the electrical charge can be achieved by varying a write pulse height, pulse duration, and/or pulse count.

In at least one embodiment, by way of the write voltage, a potential difference exists between the gate electrode and the semiconductor layer. Charge states can be stored in the dielectric layer. In the case of charge trapping sites, charges would be injected through quantum mechanical tunneling. For ferroelectric material, this would occur through a change in the polarization state.

At 606, the adjustable capacitance of the semiconductor layer is increased to discharge the electrical charge in the dielectric layer. In various implementations, a DC or a symmetric blocking/conduction voltage can be applied to the semiconductor layer at the pin- or psn-transition. In addition to non-volatile field-blocking adjustments, the same effect can be achieved temporarily by applying a voltage to the semiconductor layer. In some implementations, based on the lateral p- and n-regions, the blocking or conduction behavior of the pin- or psn-diode can cause depletion or accumulation of mobile charge carriers, thus modifying how the semiconductor layer regulates the electric field. Moreover, applying the same DC voltage to both terminals of the semiconductor layer can shift the gate voltage range for depletion in semiconductor materials, which in turn changes the field-blocking or transmission behavior by shifting the capacitance-voltage curves.

In at least one embodiment, at 606, the adjustable capacitance of the semiconductor layer is increased by grounding the semiconductor layer. In at least one embodiment, grounding the semiconductor layer can include connecting the layer to a reference voltage (e.g., 0 volts) or tying the layer to a reference potential of a circuit element, such as an operational amplifier, to establish a virtual ground for the semiconductor layer. Virtual grounding for the semiconductor layer can be achieved through various biasing circuit arrangements that provide a fixed voltage or reference point, such as a rail splitter IC, transistor-based current buffer, and the like. In at least one embodiment, the adjustable capacitance of the semiconductor layer is increased by depleting the semiconductor layer. In at least one embodiment, the semiconductor layer is depleted when one or more regions of the layer include a greatly reduced or depleted number of charge carriers (e.g., electrons or holes).

At least one embodiment, the adjustable capacitance of the semiconductor layer is increased by grounding the semiconductor layer and applying a variable voltage signal to the gate electrode layer. The process of applying the variable voltage signal and grounding can shift a capacitance-voltage curve to influence charge flow through the device via the semiconductor layer. In other implementations, the adjustable capacitance of the semiconductor layer is increased by applying a DC voltage to one or more of the doped regions of the semiconductor layer. Furthermore, readout is achieved by applying a variable voltage to the gate electrode layer and measuring a charge change at one or more of the doped regions of the semiconductor layer. In particular, in at least some embodiments, writing to the capacitive synaptic device or reading from the device can be influenced by applying a forward or reverse voltage to the semiconductor layer of the device. For example, the forward or reverse voltage to the semiconductor layer can be applied at one or more of the doped regions of the semiconductor layer.

At least one embodiment of the disclosure can be describe in view of the following clauses:
According to clause 1 this disclosure relates to a capacitive synaptic device, comprising: a semiconductor layer including a first region with a first doping type and a second region with a second doping type; a gate electrode disposed on the semiconductor layer; and a dielectric layer disposed between the gate electrode and the semiconductor layer, wherein the gate electrode and/or the dielectric layer is configured not to overlap at least one of the first doped region and the second doped region.
According to clause 2, the device according to clause 1 may comprise the following features: the first doping type comprises holes or electrons and the second doping type comprises holes or electrons; or the doping type of the first region is a n-type and the doping type of the second region is a p-type, or the doping type of the first region is a p-type and the doping type of the second region is a n-type, or the doping type of the first region is a p-type and the doping type of the second region is a p-type, or the doping type of the first region is a n-type and the doping type of the second region is a n-type.
According to clause 3, the semiconductor layer of the device according to any one of clauses 1 to 2 preferably has a thickness of 10-30 nm.
According to clause 4, the device according to clauses 1 to 3 may comprise the following feature: readout of the capacitive synaptic device is performed through the first region or through the second region.
According to clause 5, the device according to any one of clauses 1 to 4 may comprise the following features: the distance from a boundary of the gate electrode to a boundary of the first region or of the second region is preferably at least 0.1 times a total length of the gate electrode to reduce or prevent parasitic capacitance between the gate electrode and one or more of the first region or the second region; and/or the distance from a boundary of the dielectric layer to a boundary of the first region or of the second region is at least 0.1 times a total length of the gate electrode.
According to clause 6, the distance of the device according to clause 5 is adjusted with a self-aligned spacer process during manufacturing.
According to clause 7, the dielectric layer of the device according to any one of clauses 1 to 6 is an active storage medium capable of storing various charge states as to have multiple non-volatile memory states.
According to clause 8, the device according to any one of clauses 1 to 7 may comprise the following features: the semiconductor layer comprises a plurality of contacts, wherein a first contact of the plurality of contacts allows inflow electrical charge and a second contact of the plurality of contacts allows outflow of the electrical charge.
According to clause 9, the device according to any one of clauses 1 to 8 may comprise the following feature: during readout of the capacitive synaptic device, the semiconductor layer is to be coupled to ground.
According to clause 10, the device according to any one of clauses 1 to 9 may comprise the following features: a further layer of material is disposed on the gate electrode, the layer of material configured to reduce or prevent parasitic capacitance between the gate electrode and one or more of the first region or the second region and/or configured to prevent stray coupling of electrons between gate electrode and the semiconductor layer; preferably the layer of material comprises one or more conducting materials and/or the layer of material has a thickness between 5 and 20 nm.
According to clause 11, the device according to clause 10 may comprise the following features: an insulating layer is disposed between the layer of material and the gate electrode or below the semiconductor layer; preferably, the layer of material is further disposed on the semiconductor layer and is configured not to overlap at least one of the first region or the second region.
According to clause 12, the device according to any one of clauses 1 to 11 may comprise a further layer of material, wherein the semiconductor layer is disposed on the further layer of material and the further layer of material is configured to reduce or prevent parasitic capacitance between the capacitive synaptic device and another capacitive synaptic device proximate to the capacitive synaptic device.
According to clause 13, the device according to any one of clauses 1 to 12 may further comprise another gate electrode and another dielectric layer, wherein the semiconductor layer is disposed on at least the other dielectric layer.
According to clause 14, the device according to any of clauses 1 to 13 may be used as a memory component to optimize post-training quantization in the implementation of a neural network.
According to clause 15 this disclosure relates to a method to operate the capacitive synaptic device, comprising: generating voltage difference between a gate electrode and a semiconductor layer, the gate electrode disposed on the semiconductor layer, and the semiconductor layer having an adjustable capacitance and comprises a first doped region and a second doped region; based on the voltage difference, accumulating an electrical charge in a dielectric layer disposed between the gate electrode and the semiconductor layer; and increasing the adjustable capacitance of the semiconductor layer to discharge the electrical charge in the dielectric layer, wherein the gate electrode and/or the dielectric layer is configured not to overlap at least one of the first doped region and the second doped region.
According to clause 16, the method according to clause 15 may comprise the following features: the first doped region comprises holes or electrons and the second doped region comprises holes or electrons; or the doping type of the first region is a n-type and the doping type of the second region is a p-type, or the doping type of the first region is a p-type and the doping type of the second region is a n-type, or the doping type of the first region is a p-type and the doping type of the second region is a p-type, or the doping type of the first region is a n-type and the doping type of the second region is a n-type.
According to clause 17, the method according to any one of clauses 15 to 16 may further comprise discharging the electrical charge in the dielectric layer through the first doped region or through the second doped region.
According to clause 18, the method according to any one of clauses 15 to 17 may further comprise the following features: the distance from a boundary of the gate electrode to a boundary of the first region or of the second region is preferably at least 0.1 times a total length of the gate electrode to reduce or prevent parasitic capacitance between the gate electrode and one or more of the first region or the second region; and/or the distance from a boundary of the dielectric layer to a boundary of the first region or of the second region is at least 0.1 times a total length of the gate electrode.
According to clause 19, the method according to any one of clauses 15 to 18 may further comprise coupling the semiconductor layer to ground to discharge the electrical charge in the dielectric layer.
According to clause 20, the method according to any one of clauses 15 to 19 may further comprise the following features: a layer of material being disposed on the gate electrode, the layer of material being configured to reduce or prevent parasitic capacitance between the gate electrode and one or more of the first doped region or the second doped region, wherein the layer of material comprises one or more conducting material.
According to clause 21, the method according to clause 20 may further comprise the following features: an insulating layer being disposed between the layer of material and the gate electrode or below the semiconductor layer; preferably, the layer of material being further disposed on the semiconductor layer and being configured not to overlap at least one of the first doped region or the second doped region.
According to clause 22, the device according to any of clauses 15 to 21 may be operated as a memory component to optimize post-training quantization in the implementation of a neural network.

The specification and drawings are, accordingly, to be regarded in an illustrative rather than a restrictive sense. It will, however, be evident that various modifications and changes may be made thereunto without departing from the broader spirit and scope of the subject matter set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the subject matter recited by the claims to the specific form or forms disclosed but, on the contrary, the intention is to cover all modifications, alternative constructions, and equivalents falling within the spirit and scope of this disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. Similarly, use of the term “or” is to be construed to mean “and/or” unless contradicted explicitly or by context. The terms “comprising,” “having,” “including,” and “containing” are to be construed as open-ended terms (i.e., meaning “including, but not limited to,”) unless otherwise noted. The term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. The use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but the subset and the corresponding set may be equal. The use of the phrase “based on,” unless otherwise explicitly stated or clear from context, means “based at least in part on” and is not limited to “based solely on.”

Conjunctive language, such as phrases of the form “at least one of A, B, and C,” or “at least one of A, B and C,” (i.e., the same phrase with or without the Oxford comma) unless specifically stated otherwise or otherwise clearly contradicted by context, is otherwise understood within the context as used in general to present that an item, term, etc., may be either A or B or C, any nonempty subset of the set of A and B and C, or any set not contradicted by context or otherwise excluded that contains at least one A, at least one B, or at least one C. For instance, in the illustrative example of a set having three members, the conjunctive phrases “at least one of A, B, and C” and “at least one of A, B and C” refer to any of the following sets: {A}, {B}, {C}, {A, B}, {A, C}, {B, C}, {A, B, C}, and, if not contradicted explicitly or by context, any set having {A}, {B}, and/or {C} as a subset (e.g., sets with multiple “A”). Thus, such conjunctive language is not generally intended to imply that certain embodiments require at least one of A, at least one of B and at least one of C each to be present. Similarly, phrases such as “at least one of A, B, or C” and “at least one of A, B or C” refer to the same as “at least one of A, B, and C” and “at least one of A, B and C” refer to any of the following sets: {A}, {B}, {C}, {A, B}, {A, C}, {B, C}, {A, B, C}, unless differing meaning is explicitly stated or clear from context. In addition, unless otherwise noted or contradicted by context, the term “plurality” indicates a state of being plural (e.g., “a plurality of items” indicates multiple items). The number of items in a plurality is at least two but can be more when so indicated either explicitly or by context.

Operations of processes described herein can be performed in any suitable order unless otherwise indicated herein or otherwise clearly contradicted by context. In an embodiment, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In an embodiment, the code is stored on a computer-readable storage medium, for example, in the form of a computer program comprising a plurality of instructions executable by one or more processors. In an embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals.

The use of any and all examples or exemplary language (e.g., “such as”) provided herein is intended merely to better illuminate various embodiments and does not pose a limitation on the scope of the claims unless otherwise claimed. No language in the specification should be construed as indicating any non-claimed element as essential to the practice of inventive subject material disclosed herein.

Embodiments of this disclosure are described herein, including the best mode known to the inventors for carrying out inventive concepts described herein. Variations of those embodiments may become apparent to those of ordinary skill in the art upon reading the foregoing description. The inventors expect skilled artisans to employ such variations as appropriate, and the inventors intend for embodiments of the present disclosure to be practiced otherwise than as specifically described herein. Accordingly, the scope of the present disclosure includes all modifications and equivalents of the subject matter recited in the claims appended hereto as permitted by applicable law. Moreover, any combination of the above-described elements in all possible variations thereof is encompassed by the scope of the present disclosure unless otherwise indicated herein or otherwise clearly contradicted by context.

All references including publications, patent applications, and patents cited herein are hereby incorporated by reference to the same extent as if each reference were individually and specifically indicated to be incorporated by reference and were set forth in its entirety herein.

What is claimed is:

1. A capacitive synaptic device, comprising:
a semiconductor layer including a first region with a first doping type and a second region with a second doping type;
a gate electrode disposed on the semiconductor layer; and
a dielectric layer disposed between the gate electrode and the semiconductor layer, wherein the gate electrode and/or the dielectric layer are configured to not overlap at least one of the first region or the second region.

2. The capacitive synaptic device according to claim 1, wherein the first doping type comprises holes and the second doping type comprises electrons, or the first doping type comprises holes or electrons and the second doping type comprises holes or electrons.

3. The capacitive synaptic device according to claim 1, wherein the semiconductor layer has a thickness of 10-30 nm.

4. The capacitive synaptic device according to claim 1, wherein readout of the capacitive synaptic device is performed through the first region or the second region.

5. The capacitive synaptic device according to claim 1, wherein a distance from a boundary of the gate electrode or the dielectric layer to a boundary of the first region or the second region is at least 0.1 times a total length of the gate electrode or the dielectric layer.

6. The capacitive synaptic device according to claim 5, wherein the distance is adjusted with a self-aligned spacer process during manufacturing.

7. The capacitive synaptic device according to claim 1, wherein the dielectric layer is an active storage medium capable of storing various charge states.

8. The capacitive synaptic device according to claim 1, wherein the semiconductor layer comprises a plurality of contacts, a first contact of the plurality of contacts to allow inflow electrical charge and a second contact of the plurality of contacts to allow outflow of the electrical charge.

9. The capacitive synaptic device according to claim 1, wherein during readout of the capacitive synaptic device the semiconductor layer is to be coupled to ground.

10. The capacitive synaptic device according to claim 1, further comprising a layer of material disposed on the gate electrode, the layer of material configured to reduce or prevent parasitic capacitance between the gate electrode and one or more of the first region or the second region, wherein the layer of material comprises one or more conducting materials.

11. The capacitive synaptic device according to claim 10, further comprising an insulating layer disposed between the layer of material and the gate electrode, and wherein the layer of material is further disposed on the semiconductor layer.

12. The capacitive synaptic device according to claim 1, further comprising a layer of material and the semiconductor layer is disposed on the layer of material, the layer of material configured to reduce or prevent parasitic capacitance between the capacitive synaptic device and another capacitive synaptic device proximate to the capacitive synaptic device.

13. The capacitive synaptic device according to claim 1, further comprising another gate electrode and another dielectric layer, wherein the semiconductor layer is disposed on at least the other dielectric layer.

14. A method to operate capacitive synaptic device, comprising:
generating voltage difference between a gate electrode and a semiconductor layer, the gate electrode disposed on the semiconductor layer, and the semiconductor layer having an adjustable capacitance and comprises a first doped region and a second doped region;
based on the voltage difference, accumulating an electrical charge in a dielectric layer disposed between the gate electrode and the semiconductor layer; and
increasing the adjustable capacitance of the semiconductor layer to discharge the electrical charge in the dielectric layer,
wherein the gate electrode and/or the dielectric layer are configured not to overlap at least one of the first doped region and the second doped region.

15. The method according to claim 13, wherein the first doped region comprises holes and the second doped region comprises electrons, or the first doped region comprises holes or electrons and the second doped region comprises holes or electrons.

16. The method according to claim 13, further comprising discharging the electrical charge in the dielectric layer through the first doped region or the second doped region.

17. The method according to claim 13, wherein a distance from a boundary of the gate electrode or the dielectric layer to a boundary of the first doped region or the second doped region is at least 0.1 times a total length of the gate electrode or the dielectric layer.

18. The method according to claim 13, further comprising coupling the semiconductor layer to ground to discharge the electrical charge in the dielectric layer.

19. The method according to claim 13, further comprising a layer of material disposed on the gate electrode, the layer of material configured to reduce or prevent parasitic capacitance between the gate electrode and one or more of the first doped region or the second doped region, wherein the layer of material comprises one or more conducting materials.

20. The method according to claim 19, further comprising an insulating layer disposed between the layer of material and the gate electrode, and wherein the layer of material is further disposed on the semiconductor layer and is configured not to overlap at least one of the first doped region or the second doped region.
